(19) United States
(12) Patent Application Publication
(10) Pub. No.: US 2005/0112474 A1
(43) Pub. Date: May 26, 2005

(54) Method involving a mask or a reticle

(75) Inventor: Torbjorn Sandstrom, Pixbo (SE)

Correspondence Address: HAYNES BEFFEL & WOLFELD LLP, P O BOX 366, HALF MOON BAY, CA, 94019, US

(73) Assignee: Micronic Laser Systems AB, Taby (SE)

(21) Appl. No.: 10/880,358

(22) Filed: Jun. 29, 2004

Related U.S. Application Data
(60) Provisional application No. 60/524,076, filed on Nov. 20, 2003.

(51) Int. Cl. G03F 7/20; G03F 9/00

(52) U.S. Cl. 430/5; 430/394

(57) ABSTRACT

An aspect of the present invention includes a method for patterning a workpiece. Said method including the actions of coating said workpiece with a layer sensitive to a writing wavelength of an electromagnetic radiation source, placing said workpiece on a workpiece stage in a lithographic printer, said printer having a reticle or mask, with at least a first and a second area with essentially equal pattern, disposed between said radiation source and said workpiece, patterning at least a part of said layer sensitive to said writing wavelength of said electromagnetic radiation source by illuminating said mask or reticle with at least two pulses of said electromagnetic radiation, wherein said first and second areas on said mask or reticle are superimposed on the same area of the workpiece. Other aspects of the present invention are reflected in the detailed description, figures and claims.

### RELATED APPLICATION AND PRIORITY CLAIM

This application is related to and claims the benefit of U.S. provisional application No. 60/524,076, filed Nov. 20, 2003, by the same inventor, entitled “Method And Apparatus For Printing Patterns With Improved CD Uniformity”, which is hereby incorporated by reference.

### TECHNICAL FIELD

The present invention relates to an improved lithographic method. In particular, it relates to a multi-exposure method for improving CD uniformity. One method involves exposing a die using multiple areas of a mask or reticle having a plurality of either essentially similar or varying patterns.

### BACKGROUND OF THE INVENTION

Production of high density, high performance, ultra-large scale integrated semiconductor devices demands sub-micron features, increased transistor and circuit speeds, and improved reliability. These demands require formation of device features with high precision and uniformity, which in turn necessitates careful process monitoring.

Within the semiconductor industry, a number of prior art methods are available for patterning a resist layer. For instance, one commonly used method is sometimes referred to as “step and repeat” or “stepping”, using a “stepper” or a step-and-repeat mask aligner. A stepper 100 is depicted in FIG. 1. This simplified illustration includes a radiation source 10, a beam shaping optical system 14, an illumination optical system 16, a mask or a reticle 20, a mask or reticle stage 25, a projection optical system 30, a workpiece 40, a stage 50 and a controller 60. The workpiece 40 is coated with a radiation sensitive or resist layer and placed on the stage 50 in the stepper 100. The radiation source 10 may provide pulsed light of a wavelength of about 248 nm in the deep ultraviolet region. The reticle or mask 20 is provided between the radiation source 10 and the workpiece 40. The mask or reticle 20 has transparent and opaque regions that correspond to the desired pattern to be printed within the resist layer. The beam shaping optical system 14 serves to expand the beam diameter of the laser light coming from the radiation source 10. The illumination optical system 16 is uniformly illuminating the pattern on said mask or reticle 20 placed on said reticle stage 25 with the light from the beam shaping optical system 14. Through this illumination optical system 16, the mask or reticle surface is illuminated with a uniform luminance distribution.

The projection optical system 30 projects, in a reduced scale, the pattern on said mask or reticle 20 onto the surface of the workpiece 40 placed on the stage 50. The controller 60 may control various process conditions necessary for the projection exposure of the wafer, for instance the movement of the stage 50 and different parameters of the radiation source 10 and illumination system.

The workpiece 40 is aligned to the mask or reticle 20. After said aligning, the stage 50 is moved to the first place of the workpiece 40 to be patterned. When the mask or reticle 20 is exposed to the electromagnetic radiation pulse, the transparent sections of the reticle or mask 20 allow a significant amount of the radiation to pass through the mask or reticle 20. After exposing the first area, which is usually performed by numerous laser pulses, said stage 50 is moved to next area to be patterned, i.e., a first area of the workpiece is fully exposed by all of its radiation pulses before the workpiece 40 is moved to another unexposed area. Other lithographic printers include scan-and-repeat or step-and-scan mask aligner (“scanners”) and proximity mask aligner.

Printing gates for microprocessors and of contact holes with proper degree of CD and overlay control is difficult or impractical when using the lithography techniques described above. CD control for gates and contact holes impacts microprocessor clock and memory access frequencies. CD and overlay control both impact device yield. Similarly, when printing memory devices and image sensors, CD and placement of the elementary features directly affect the performance and market value of finished devices.

One of the largest contributors to CD variation is reticle CD control and linearity. This is especially true when using binary masks, because of high inherent mask error enhancement factors (MEEF) encountered when printing fine-pitch patterns with binary masks. The so-called MEEF is an empirical measure, expressed as
Error on the mask=Error on the reticles*MEEF
MEEF expresses magnification of reticle errors and has been observed to range up to 4.

Another recognized error source is focus control and aberrations of the scanner lens. These error contributors become most significant when strong RET strategies are required with extreme off-axis illumination.

The inventor has found another previously neglected error source: speckle (or micro-non-uniformity) in the illuminator. The speckle has become more important with the use of narrow-band laser sources and polarized radiation. The speckle is a grainy variation in illumination E across the reticle due to beating between the laser modes and between different beamlets being split and recombined in the illuminator optics. The RMS value of the speckle, according to the inventor, follows the general rule:
Erms=Erms, dynamic+Erms, static

The dynamic part of speckle varies from exposure to exposure, depending on the degree of polarization and the number of temporal coherence lengths in the exposing light (20-50 laser pulses normally).
E_{rms,dynamic}=1/sqrt((2−P)*Tₑ/t_{c})
where P is a factor from 0 to 1, with 0 denoting non-polarized and 1 fully polarized light; Tₑ is the total illumination time for a feature, typically 40 pulses times 50 ns; and t_{c} is the time corresponding to the temporal coherence length.

The static part of Eᵣₘₛ is a stationary pattern created by the illuminator itself. It has been found to obey the formula
E_{rms,static}=_{C}_{design}/sqrt(N).
where C_{design} is a factor between 0 and 1 dependent on the illuminator design (fly-eye integrators, integrating light rod, diffractive homogenizers, etc) and N the number of lateral coherence cells on the input to the illuminator. The stationary part of the micro-non-uniformity is partially, but not fully, averaged by the scanning of the stage and reticle in the scanner.

The illumination variation caused by speckle produces high spatial-frequency CD and placement variations that impact individual gates or contacts. Furthermore, the speckle causes phase variations in the illumination field that degrade CD uniformity faster with defocus than it would without the speckle.

Reducing stationary micro-nonuniformity is a matter of good component and system design, but reducing dynamic speckle micro-nonuniformity requires decreased polarization, increased integrated exposure time per field, and/or decreased coherence length. Some ways to reduce micro-nonuniformity in a scanner and by exposure job setup have been described in a provisional patent application by the same inventor, U.S. patent application No. 60/524,076, entitled “Method And Apparatus For Printing Patterns With Improved CD Uniformity”, which again is incorporated by reference.

### SUMMARY OF THE INVENTION

In view of the foregoing, one object of the present invention is to improve the CD uniformity in a pattern exposed through a reticle or a mask.

An aspect of the present invention is to improve CD in the presence of speckle by voting multi-exposure of a pattern using redundant areas on a reticle. Exposure with the redundant areas that inevitably have small variations produces an averaging effect that is different from multiple exposures using the same area of the reticle.

Another aspect of the present invention includes a method for patterning a workpiece, including the actions of coating said workpiece with a layer sensitive to a writing wavelength of an electromagnetic radiation source, placing said workpiece on a workpiece stage in a lithographic printer, said printer having a reticle or mask, with at least a first and a second area with essentially equal patterns, disposed between said radiation source and said workpiece, patterning at least a part of said layer sensitive to said writing wavelength of said electromagnetic radiation source by illuminating said mask or reticle with at least two pulses of said electromagnetic radiation, wherein pulses through said first and second areas on said mask or reticle are superimposed on the same area of the workpiece.

Another aspect of the invention is to improve CD uniformity by multiple exposures overlaying images of separate areas of the reticle. The overlaid areas may contain pattern details that are not identical, i.e., that phase-shifted areas in a phase-shifting reticle may be different in the separate areas, effectively reducing asymmetries and phase conflicts.

In some regards, the methods described herein are not limited to steppers/scanners, but can be used in a maskless system as well. An optical maskless system, e.g., as described in patent applications by the same inventor, has a similar issue with speckle as a stepper/scanner. Multiple passes are used in the maskless system to average out both speckle and other imperfections in a single-pass image. Optionally, differences between images projected in multiple passes of the maskless system can be used with the same effect as in a reticle-based system. Methods described for optical maskless systems may also apply to maskless systems using photon or charged-particle exposure or near-field effects, and to maskwriters using optical SLMs or photon, electron, or particle-beam modulator arrays.

Other objects, aspects, features, and advantages of the present invention will be apparent from the accompanying drawings and from the detailed description that follows.

### BRIEF DESCRIPTION OF THE DRAWINGS

FIG. 1 depicts a schematic side view of a stepper according to prior art.

FIG. 2 depicts a mask or a reticle with four essentially equal areas.

FIG. 3 depicts a wafer patterned with the mask or the reticle illustrated in FIG. 2.

FIG. 4 depicts how multiple writing passes reduce speckle.

FIGS. 5a-5b depict printing features using a reticle with phase-shifted areas. FIGS. 5c and 5d illustrate a mask or reticle comprising a phase edge pattern and a trim pattern, and the resulting image.

FIGS. 6a-6f illustrate how scan-direction asymmetry is removed with multipass exposure.

FIGS. 7a-7b show the reduction of errors along and across the scanning directions.

FIG. 8 shows a reticle with four areas and related scribe lines.

FIG. 9 shows how a finer address grid than supported by the mask writer is printed.

FIGS. 10a-10c show a movable phase plate in an illuminator, that moves between flashes and/or exposure passes. The figure shows in schematic form three common types of illumination integrators: the fly-eye or lenslet array, the light-pipe or integrating rod, and the double-diffuser illumination integrators. In the latter case, the moveable phase plate can be separate from or can be one of the diffusers (as shown).

FIG. 11 depicts a phase plate in a beam homogenizer comprising two pairs of lenslet arrays.

FIGS. 12a-12f depict different methods of printing assist features in multiple writing passes.

FIG. 13 depicts one embodiment of a reticle/mask with four areas.

FIG. 14 depicts another embodiment of a reticle/mask with four areas.

FIG. 15 depicts a flowchart for manufacturing a chip.

### DETAILED DESCRIPTION

The following detailed description is made with reference to the figures, in which like references indicate similar elements. Preferred embodiments are described to illustrate the present invention, not to limit its scope, which is defined by the claims. Those of ordinary skill in the art will recognize a variety of equivalent variations on the description that follows.

FIG. 2 illustrates a reticle or mask 200 with four essentially equal areas 210, 220, 230, 240, collectively, the reticle field. These areas are essentially equal—they are intended to be equal, but production of the reticle introduces some variations or inaccuracies. Areas 210, 220, 230, and 240 include redundant instances of the pattern to be written on a workpiece, which are not shown in the figure. Surrounding the reticle field is an opaque region 260. The opaque region 260 optionally includes transparent windows 250 with alignment marks and an area 270 with a bar code pattern and/or man-readable serial number information. The number of essentially equal areas may be two or more, depending on the size of the area to be written, for instance, more for a small memory circuit than for a processor circuit.

Before applying the methods described herein, most reticles even for large circuits like memories and microprocessors have at least two patterns on the reticle. Few chips are larger than 400 square millimeters while the useable field in a scanner is typically 26 by 32 mm, i.e., over 800 square millimeters. Many chips are much smaller, down to less than 1 square millimeter. It is therefore normal that the reticle is an array of pattern areas, at least a 2×1 array, but often many more patterns.

Reticles with multiple patterns typically produce a corresponding number of dies on the workpiece, relying on multiple exposures to produce averaging. Problems with alignment, variation between patterns and reduced throughput strongly favor relying on multiple exposures to produce averaging.

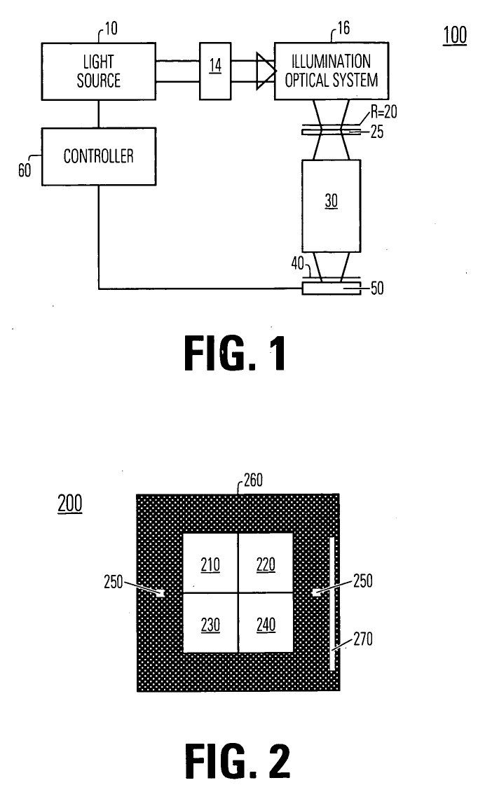

The reticle 200 appears between the electromagnetic radiation source 10 and the workpiece 40 in FIG. 1. The projection optical system 30 demagnifies the essentially equal areas of reticle 200 that are projected onto workpiece 40.

It is known in the art to use a light-diffracting pattern on the illumination source side of the reticle substrate or in a similar location to modify the angular spread of the illumination of the reticle. One optional aspect feature of the invention is to provide a DOE (diffractive optical element) that modifies the illumination at least one of the areas on the reticle. The DOE splits the light from the illuminator to new angles and the angular distribution of illumination can be changed from one area to the next on the reticle. The scribe lines may be wide enough that the light cones from the DOE hit only one pattern area on the reticle. For instance, one can use a double-dipole decomposition between the pattern areas of the reticle and use DOEs to split a small-sigma illumination setting into one double dipole for each pattern areas, and with each dipole oriented as the decomposed pattern requires.

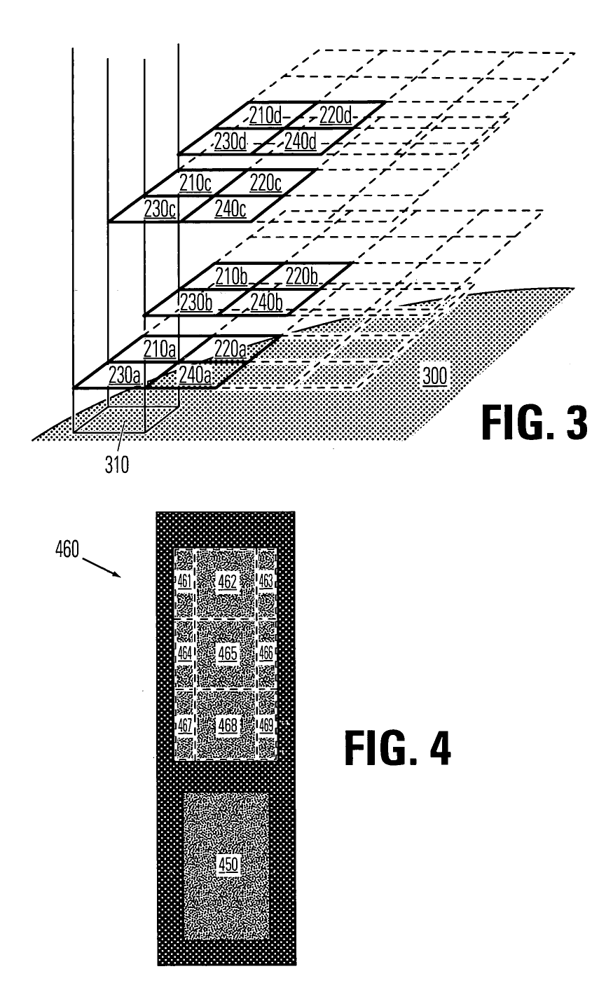

FIG. 3 illustrates a portion of a wafer 300 patterned with a reticle field having four essentially equal areas 210, 220, 230, 240. A first writing pass is denoted by a, a second pass is denoted by b, a third pass is denoted by c and a fourth pass is denoted by d. A chip area 310 on the wafer has been patterned with at least one exposure of area 210c, at least one exposure of area 220b, at least one exposure of area 230a, and at least one exposure of area 240d. That is, reticle areas 210, 220, 230 and 240, are superimposed on each other in workpiece area 310, where the a, b, c, d indicate from which writing pass said particular area is coming from. The area 310 may correspond to a single die or several dies. The reticle can have an 8 by 4 array of chips and the area 310, being one fourth of the reticle area, can have a 2 by 1 array in it.

This way to print a single die by overlaid exposures between different areas of the same reticle field is called “voting exposure” herein, because the result of exposures using different reticle areas is conceptually the result of an average or voting process between the reticle errors in the different areas. It is also an average or voting between the speckle patterns and the dynamic focus and stage errors during the different exposure steps. Using exposure passes is known in art of pattern generators, but voting exposure using different reticle areas with essentially equal patterns is novel and contrary to considerations involving alignment errors and throughput.

Voting exposure for steppers and scanners may improve several things at the same time, such as less illuminator speckle, less systematic non-uniformities of illumination, less contribution from mask CD, less sensitivity to defects on the mask, less impact of lens distortion and aberrations, averaging of scanning errors, and averaging of focus errors. Any of these advantages could be significant; not all embodiments will gain all of these improvements.

In some applications, only the most critical layers of a design will be patterned using a multi-exposure voting method. A state-of-the-art chip design may have a total number of different layers being 30 or more. Only some of these layers must be patterned with particularly high accuracy. Voting exposure may be applied to the most critical layers only. The inventor believes that a loss in throughput can be offset by improved quality of small features, resulting in an increased selling price for the end product, even when voting exposure is applied only to one or two layers. Selective application of voting exposure reduces the increase in production. Furthermore, when the exposure time per die is speckle-limited or extended to overcome speckle effects, relatively shorter exposure time for voting exposure may reduce or offset the throughput loss.

FIG. 4 illustrates reduction of speckle by a plurality of exposures. The lower part of the FIG. 450, illustrates a white image with speckle. Speckle is the grainy portions of the image. The contrast of the speckle, which in reality may have an rms value of 1-3%, is exaggerated for visibility. An upper part of the same FIG. 460, illustrates improvement in speckle resulting from four exposure passes partially overlapping each other. Area 461 simulates speckle after a first pass. Area 462 simulates speckle after first and second passes. Area 463 simulates speckle after just the second pass, without superimposition of the first pass. Area 464 simulates results of the first and third passes. The least speckled area 465 simulates the combined result of all four exposure passes. Area 466 simulates the second and fourth passes. Area 467 simulates just the third pass. Area 468 simulates the third and fourth passes. Area 469 simulates just the fourth pass The upper part of the FIG. 460, simulates how speckle is reduced by the number of overlapping exposures: the areas with two passes are better than the areas with only one pass and the area with four passes is better than the areas with only two passes. Better, of course, means that less graininess is visible as more overlapping exposures are used.

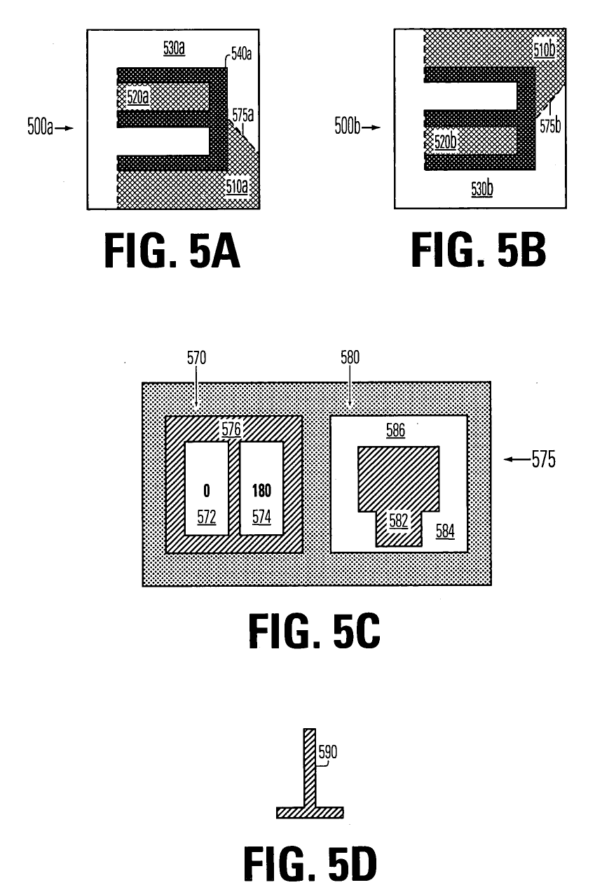

Application of voting exposure to phase-shifting masks with differing phase-shift regions is illustrated in FIGS. 5a-b. FIG. 5a illustrates a simplified pattern 500a on phase-shifting mask. Pattern 500a includes a feature 540a, blank areas 530a, and phase-shifted areas 510a and 520a. Use of phase shifted areas 510e and 520a improves the resolution of feature 540a. The phase-shifted areas 510a, 520a may be 180 degrees out of phase compared to the clear or blank areas 530a. In one embodiment, the phase shifted areas 510e, 520a have essentially the same transmission as the blank or clear areas 530a. In another embodiment, phase shifted areas 510a, 520a are attenuated compared to the clear or blank areas 530a. Applied to voting exposure, one of the essentially equal areas 210, 220, 230 or 240, in FIG. 2, has a pattern 500a and another has a pattern 500b, in FIG. 5b. Feature 540b of pattern 500b is identical to the feature 540a of pattern 500a, but the phase shifted and clear areas have been rearranged. The phase-shifted areas are denoted 510a-b and 520a-b and the clear area is denoted 530a-b. Patterns 500a and 500b are superimposed by successive exposure on a particular area of the workpiece. Variation of (optionally, reversal) of the shifted and non-shifted areas between the partial exposures addresses an asymmetry problem with phase-shifting masks that the clear and shifted areas do not match exactly, due to phase errors and the 3D electromagnetic boundary conditions at the edges.

In FIGS. 5a and 5b, the boarder 575a/b between phase-shifted area 510a/b and clear area 530a/b is not coincident. A weakness of phase-shifting masks is that butting of a shifted area to a non-shifted one may create a dark line. By application of voting exposure, borders 575a/b can be moved to different positions, mitigating the dark area that results from phase conflict at the boundary between shifted and non-shifted areas. With the näive layout in FIG. 5 there would still be some artifacts, but software for model-based OPC can readily be adapted to suppress the artifacts strongly. Voting exposure-aware OPC software would first identify the phase conflicts and generate patterns for the different layers that avoid repeated exposure with the same placement of the phase boundary. It would then simulate the aerial image (and/or resist image) after the multipass exposure and compare the result to the desired exposure pattern. It would then modify at least one of the multiple exposures (i.e., areas on the reticle) in order to correct differences from the desired pattern. This voting exposure-aware OPC software, described in the context of strong phase shifting, also has utility for other types of reticles, e.g., binary and attenuated masks as will be described below.

In a further embodiment, one area of the mask or reticle may be used to form a part of a feature with OPC corrections or “jogs” that is different from features or OPC corrections in another area of the same mask or reticle. FIG. 5c illustrates a mask or reticle 575 including a phase edge pattern 570 and a trim pattern 580. The phase edge pattern 570 and the trim pattern 580 are in different areas of the same mask or reticle 575. The phase edge pattern 570 includes an opaque area 576 and two clear areas 572 and 574. Area 574 is 180 degrees phase shifted from area 572. The trim mask includes a pattern 582 surrounded by a clear area 584. A superposition in successive exposures of the phase edge pattern 570 and the trim pattern 580 will result in an image as depicted in FIG. 5d. The use of a phase edge and a trim mask are well known in the art, but not in combination with voting exposure or multipass printing from a single reticle. Instead, the practice is to use a phase-shifting mask and expose the wafer, then change reticle to the trim mask and expose again. This procedure involves either realigning all wafers between each exposure or alternatively, realigning the reticles for every wafer. With voting exposure or multipass exposure with phase shifting and trim mask areas on the same reticle, neither the wafer nor the reticle needs to be realigned between the partial exposures, thereby assuring better overlay.

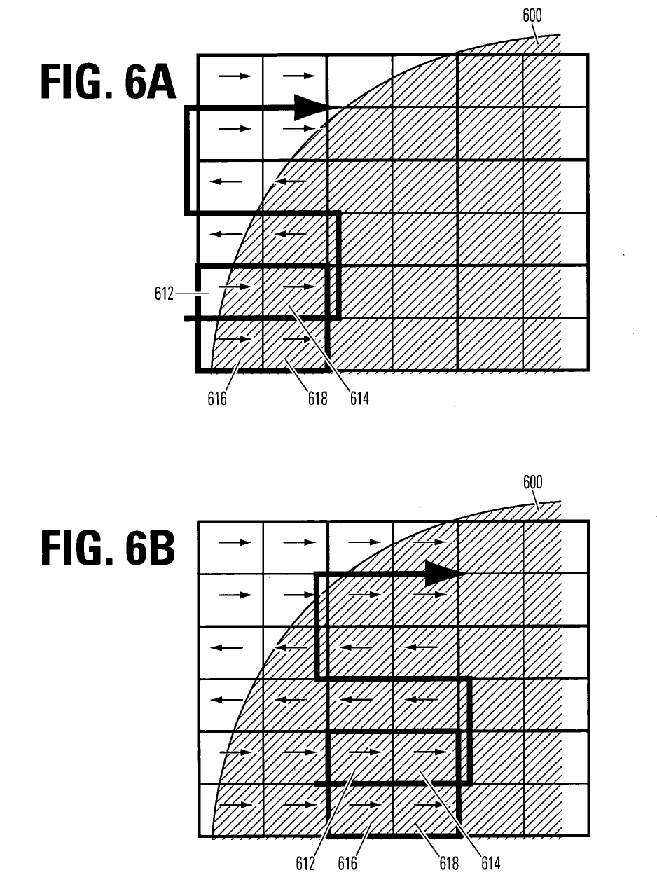

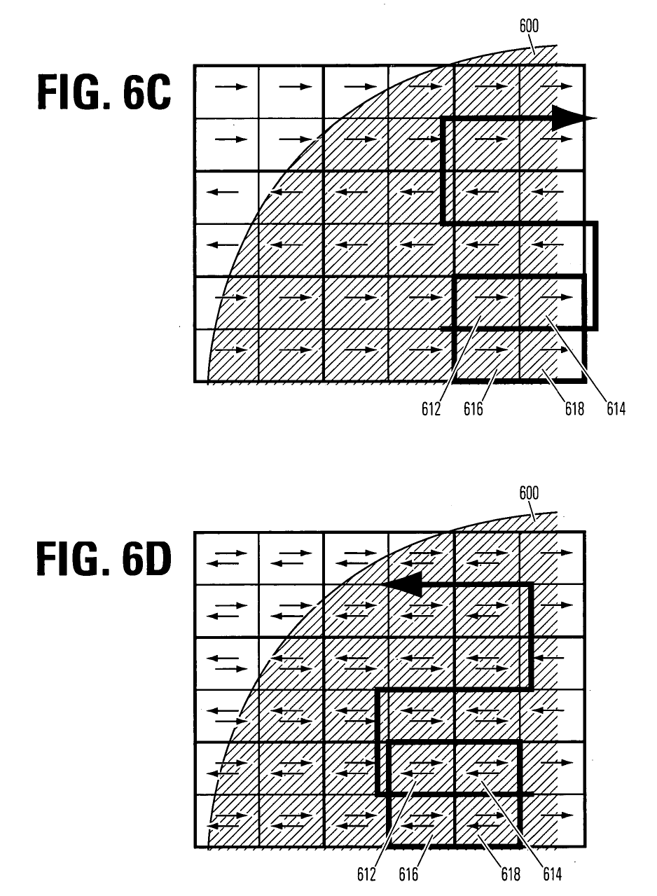

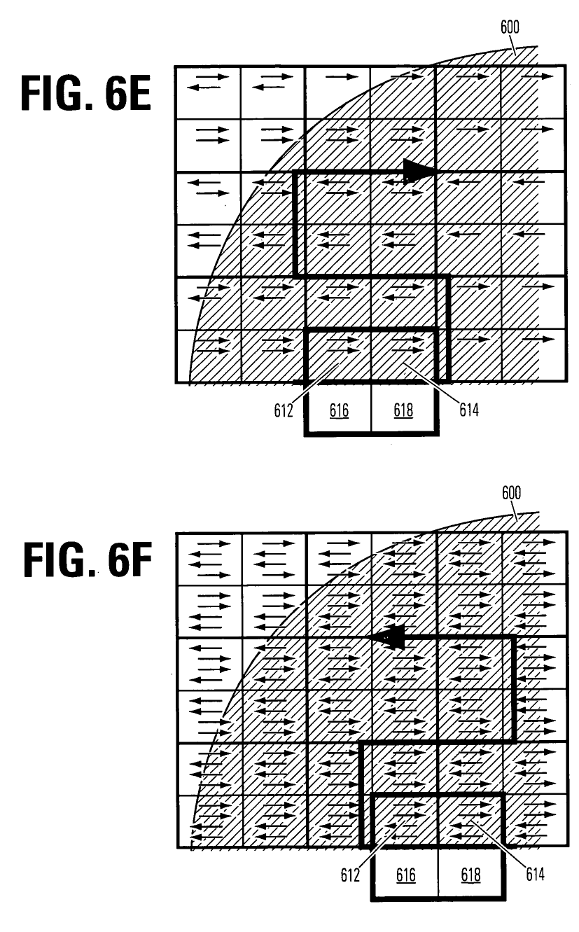

Reversing scan directions and using multiple areas of a reticle to expose a die on a workpiece may be combined to reduce scan-direction errors in a scanner. The scan direction is often visible in CD maps and yield maps of processed wafers, when a scanner is used. FIG. 6a illustrates the scan directions for a wafer 600 in the scanner. The mask or reticle includes four areas 612, 614, 616, 618 with essentially equal pattern. At a first position of the mask/reticle, denoted by a solid frame 610 around the four areas, the scanning direction of the slit is to the right. At a second position, the scanning direction of the slit backtracks to the left. At a third position, the scanning direction of the slit is again to the right. FIG. 6a illustrates three exposure positions of the mask/reticle on the wafer in a first column. FIG. 6b illustrates another three exposure positions of the mask/reticle on the wafer in a second column, and FIG. 6c illustrates positions in a third column. FIGS. 6a-6c illustrate a first writing pass.

FIG. 6d illustrates a first mask displacement for a second writing pass that uses multiple areas of the reticle to expose a die and reverses the scanning direction in the second writing pass. In FIGS. 6a-6c, the scan directions in the columns were chosen so that each row has a constant direction. In FIG. 6d, the exposure positions of the mask/reticle in the second pass are displaced compared to the first exposure positions of the mask/reticle. The displacement is performed in X-direction and has been chosen to coincide with a length of the area 612, 614, 616 or 618. In FIG. 6d, the scan directions in the columns of the second pass create rows scanned in the same direction, which is generally opposite to the direction in FIGS. 6a-6c. In this way, every die is exposed once to the right and once to the left. The combination of scanning in essentially opposing directions and voting exposures may make any errors significantly smaller.

FIG. 6e illustrates a second mask displacement for a second writing pass that uses multiple areas of the reticle to expose a die and reverses the scanning direction in the second writing pass. In FIG. 6f, displacement and opposing writing passes are extended to four writing passes. In FIG. 6e, the exposure positions of the mask/reticle in the second pass are displaced in Y-direction compared to the first exposure positions of the mask/reticle. The displacement coincides with a height of the areas 612, 614, 616 or 618. In a third writing pass out of four, not illustrated, the mask/reticle is displaced in X-direction, coinciding to a length of the areas 612, 614, 616 or 618 on said wafer 600. After four passes, different dies have right-right, right-left, left-right and left-left scanning.

FIG. 6f illustrates a fourth writing pass out of four writing passes. In FIG. 6f, the exposure positions of the mask/reticle in the fourth pass are displaced compared to the first exposure positions of the mask/reticle in X-direction and in Y-direction and has been chosen to coincide with a length and height of the areas 612, 614, 616 or 618. After having completed said fourth writing pass, every exposed die has been exposed to each of the areas 612, 614, 616 and 618 on the reticle. The third and fourth pass also produce dies with right-right, right-left, left-right and left-left scan directions, but that the four passes together make all dies have the same number of right and left scan strokes. By planning the scanning direction of the slit in a systematic way repeatable scan-direction distortions, normally appearing as a checkerboard patterns in the processed wafer, may be avoided. Special software may be used to create a good scan pattern for each multi-exposure scheme. The separate passes must be understood in a principal manner; the scanning sequence may print the entire wafer and then scan the entire wafer once more for a second pass, or it may scan all displaced passes in one row of the wafer in sequence, or the scan sequence can scan all overlaid passes of a single die in subsequent scans. The order by which the scans and passes are done is not of primary importance and can be modified for optimized throughput, overlay, CD uniformity or other desired property.

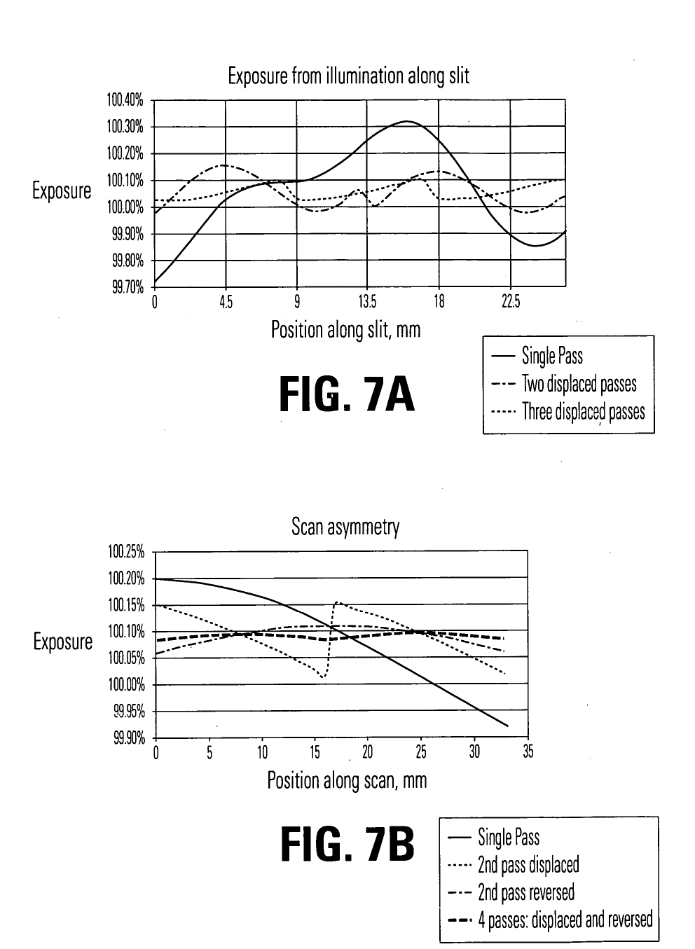

FIG. 7a illustrates a conceptual graph with exposure dose as a function of a position along a slit in a projection printer, for instance a scanner. A solid line represents exposure variations along a slit for a single writing pass, i.e., 100% of the exposure dose is impinging onto the wafer in one pass. A dashed dotted line represents two displaced passes—the exposure from two displaced passes has a more even distribution than a single pass. A dotted line represents three displaced passes. This writing strategy improves the uniformity of the exposure distribution along the slit.

FIG. 7b illustrates a conceptual graph with exposure dose as a function of position along a scan direction of the slit. A solid line represents a single pass. The exposure at the x-origin is higher than to the right. A dotted line represents 2 passes displaced from each other. A dashed dotted line represents two passes displaced from each other, where the second pass has a reversed scanning direction of the slit compared to the first pass. The figure illustrates is a major improvement between the two pass writing strategy with displacement and reversed scanning direction of the slit compared to two pass writing strategy with displacement but without reversed scanning direction of the slit. Yet further improvement can be achieved by a four pass writing strategy, with displacement and reversed scanning direction of the slit, as denoted by a bold dashed line. Correction of exposure dose is one improvement resulting from the writing strategies described. Other sources of error, such as focus, distortion, wafer-reticle synchronization etc., may similarly be improved by the writing strategies described.

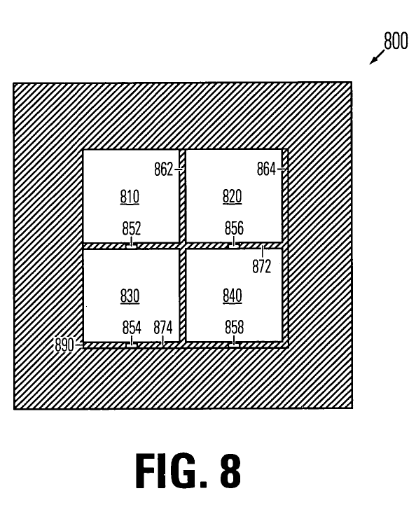

FIG. 8 illustrates a reticle/mask 800 with four areas 810, 820, 830, 840 in the reticle field. Areas 810, 820, 830 and 840 are separated by so-called scribe or saw lines 862, 872. Additional scribe lines are located to the right of (864) and below (874) the reticle field. Scribe lines 864, 874 are going to be between different reticle/mask fields, i.e., interfield scribe lines, whereas the scribe lines 862, 872 are within a reticle/mask field, i.e., intrafield scribe lies. With the voting exposure or multipass printing, the intra- and interfiled scribe lines coincide when a mask is displaced by the length or height of a mask area. A width of scribe line 862 may be identical to scribe line 864. Similarly, the widths of scribe lines 872 and 874 may be identical. Of less significance, width of horizontal scribe line 872 may be identical to vertical scribe line 862. Within scribe lines 872 and 874, one or more test pattern areas 852, 854, 856 and 858 may appear, which can used as a functionality test for the pattern in areas 810, 820, 830 and 840. At least parts of the test pattern in some of said test pattern areas 852, 854, 856 and 858 (depending on the multipass scheme) should be identical, since each test pattern exposed on the wafer if formed by the superposition from two or more test pattern structures on the reticle.

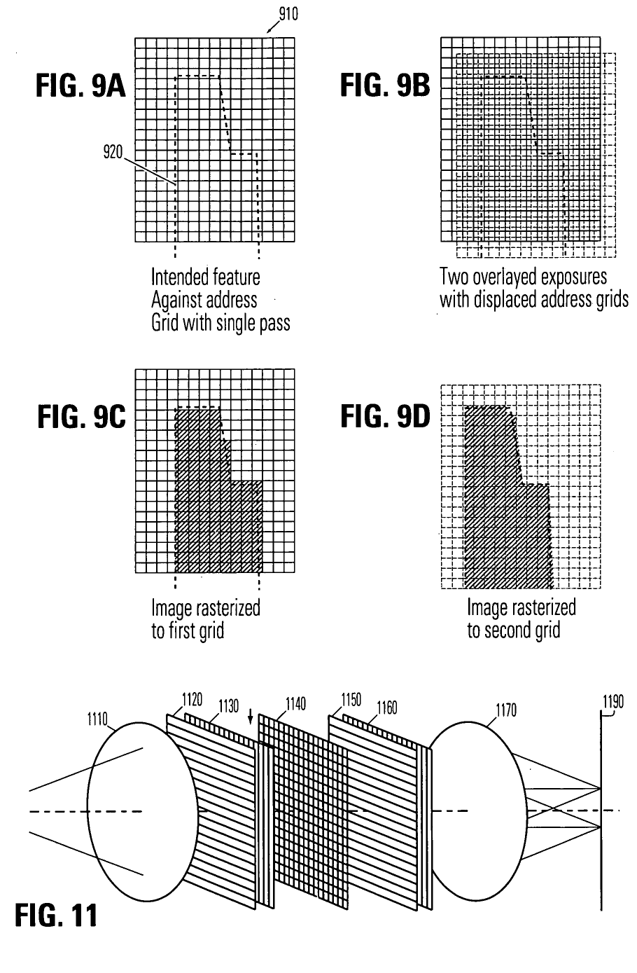

FIG. 9a illustrates an intended feature 920 to be patterned in an address grid 910. It is evident from the figure that the intended feature and the address grid do not match. If the feature 920 were written in a single pass using the indicated address grid, the feature would most likely be to small or too big, depending on the truncation criteria. Voting exposure provides a way of improving the match between the intended and written features. The address grids used in said two writing passes may be displaced, as illustrated in FIG. 9b.

FIG. 9c illustrates how rasterized feature 920, in the first pass, is smaller along some edges than the intended feature image. FIG. 9d illustrates how the rasterized feature in the second pass, again indicated by a hatched area, is slightly bigger than the intended feature. In one method, the small and bigger rasterized features are superimposed in exposures with the same dose. Said first and second grid may be displaced relative to each other, as mentioned above, potentially improving the match between the intended feature and the written feature.

The degree of displacement of the first and second grid relative to each other determines is a fine adjustment. With N overlaid exposures, the grid can be displaced by a factor of 1/N along each axis. The pattern design software or the mask data preparation software prepares image files so that the truncation to the grid in each partial exposure results in a finer address grid in the voted image. Alternatively, the multi-exposure rasterization can be done in the mask writer under control of a multi-exposure-aware command or script file. One way to implement a grid offset and achieve a finer grid is to send the rasterization system data with high resolution and a geometrical offset of a fraction of a pixel, plus a command to shift the stage origin while writing in order that the original data is not shifted versus the coordinates of the mask blank.

The division of the grid has been shown for a raster-based pattern generator, but it can equally well be applied to any other pattern generator. For vector-oriented writers, there is likewise a built-in address grid and the data can be shifted relative to the grid of the writer, then shifted back during writing by an offset of the stage, the shift being different between the passes. This will create the finer grid.

As mentioned above, speckle can be considered to have dynamic and static micro-nonuniformity characteristics, when using a partially coherent laser beam. The dynamic speckle is reduced by multiple exposures, but the stationary micro-nonuniformities are coincident and keep repeating. An additional feature can be added to projection systems to reduce the stationary part of the micro-nonuniformities, which modifies the phase relation between light traveling along different paths through the illuminator to the mask is changed between the exposures.

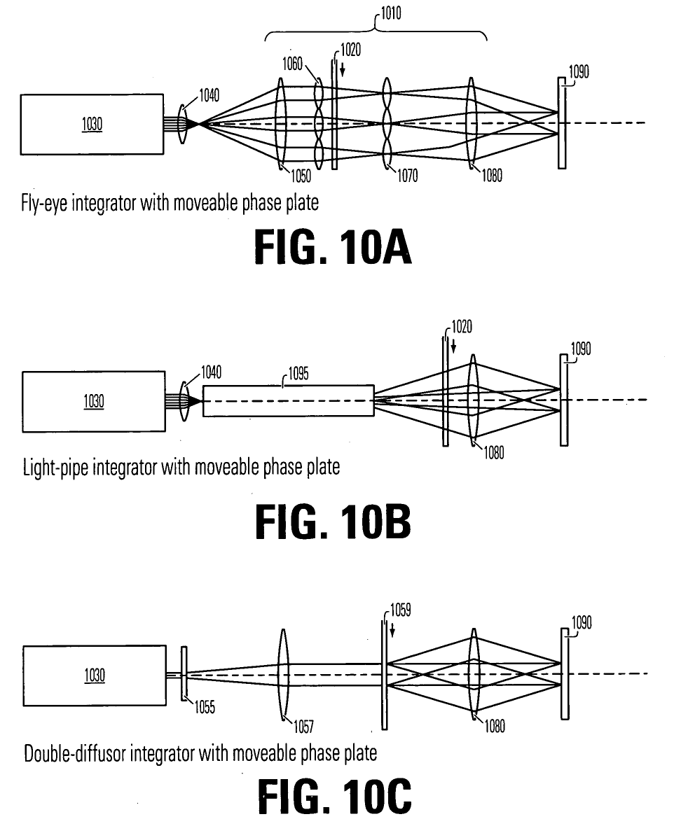

FIGS. 10a-d illustrate embodiments that reduce static micro-nonuniformity on the workpiece. FIG. 10a illustrates a fly-eye integrator 1010 equipped with a phase plate 1020 that moves between the exposures. FIG. 10a depicts a laser 1030, a first lens 1040, a fly-eye integrator 1010 and a reticle 1090. The fly-eye integrator includes a front lens 1050, a first set of fly-eye lenses, the phase plate 1020, a second set of fly eye lenses 1070 and a final lens 1080. The phase plate 1060, between the first and second sets of fly-eye lenses, may be movable. The phase plate may have phase steps. The phase at different points in the phase plate may be chosen randomly, semi-randomly or systematically between two or more values in the range of 0-360°. The phase also could be selected from a wider range. The pattern of the phase plate may be computer generated in order to reduce speckle in a pattern on said reticle 1090 as much as possible. A size of altering phase steps may differ across the phase-plate (or a diffuser, in the following embodiment) in a random, semi-random or systematic manner. The phase plate is moveable between exposures, which may involve multiple pulses, and may also be moveable during each exposure, between the laser pulses. As illustrated, the first lens 1040 enlarges the beam spot size in order to illuminate the complete size of the front lens 1050. The front lens 1050 collimates the beam. The first and second set of fly eye lenses homogenize the beam according to well-known techniques that a person skilled in the art will understand without no further clarification here. The homogenization is shown only in one dimension, however 2-dim homogenization may be easily implemented and is further explained in relation to FIG. 11 below. The final lens focuses the different beamlets onto the workpiece 1090.

FIG. 10b illustrates a light pipe beam homogenizer, as an alternative to fly-eye lenses. FIG. 10b includes a laser 1030, a first lens 1040, a light pipe 1045, a phase plate 1020, a final lens 1080 and a reticle 1090. The phase plate is typically arranged between the light pipe and said final lens. The phase plate 1020 may be movable. The phase plate may have phase steps chosen as describe above, with reference to FIG. 10a.

FIG. 10c illustrates another embodiment, a double diffuser integrator and beam homogenizer. FIG. 10c includes a laser 1030, a first diffuser 1055, a first lens 1057, a second diffuser 1059, a final lens 1080 and a workpiece 1090. The two diffusers (or computer-generated diffractive elements) define both the illumination field and the angular subtense of the illumination at the reticle. The phase between and during exposures is scrambled by a moveable phase-plate (not shown) between the laser and the reticle or by moving one of the diffusers (shown).

In all three embodiments of FIGS. 10a-c, the movable phase plate further destroys the likelihood that two adjacent beamlets will interfere with each other on the workpiece, producing speckle.

In one method embodiment, the phase-plate is arranged at a first position in a first writing pass and at a second position in a second writing pass. Again, the phase plate may also be moved between individual laser pulses.

FIG. 11 is an alternative embodiment of a beam homogenizer. Said homogenizer comprising a collimating lens 1110, a first pair of cylinder lenslet arrays 1120, 1130 one horizontally and one vertically oriented (could also be a single 2D lenslet array) and a second pair of cylinder lenslet arrays 1150, 1160 one horizontally and one vertically oriented. Between said first pair of cylinder lenslet arrays 1120, 1130 and said second pair of cylinder lenslet arrays 1150, 1160 is arranged a 2 dimensional phase plate 1140. The phase plate 1140 is arranged movable between said first 1120, 1130 and second arrays of lenslet arrays 1150, 1160. To understand the function of the beam homogenizer, one may look at the horizontal lenslet array 1120. An inhomogeneous illumination that falls on said lenslet array 1120 is divided into beamlets that have separated foci at one focal length's distance. After the focus, the beamlets spread again and a focusing lens 1170 directs each of them to illuminate the same area in a homogenized plane 1190. The second horizontal lenslet array 1150 has a focal length that is the same or nearly the same (e.g. 40 mm vs. 25 mm) as the first horizontal lenslet array 1120. Said second horizontal lenslet array 1150 is placed near the focus of the first horizontal lenslet array 1120 and makes an image of the first lenslet array 1120 at the homogenized plane 1190, thereby making edges of the illuminated area sharper, so that an almost ideal flat-illuminated area is created.

The horizontal lenslet arrays 1120, 1150 only homogenize the illumination in vertical direction. The vertical cylinder lenslet arrays 1130, 1160 work in the same way and homogenize the beam in the horizontal direction. Despite the arrangement of two pair of cylinder lenslet arrays as disclosed above there might still be some static non-uniformity in the homogenized plane. By introducing said phase plate 1140 near said first pair of cylinder lenslet arrays 1120, 1130 and said second pair of cylinder lenselet arrays 1150, 1160, the homogenization of the illumination may be further improved. Said phase plate is introducing a phase pattern in said illumination, which will further decrease the likelihood of having an interference with beamlets in the homogenized plane causing speckle. In one embodiment said phase plate 1140 may comprise a random or systematic phase pattern with a constant phase over each facet. A size of said semi-randomly altering phase steps may alter throughout the phase plate in a random or systematic manner. The phase plate may be moveable between exposures and possibly also during exposures.

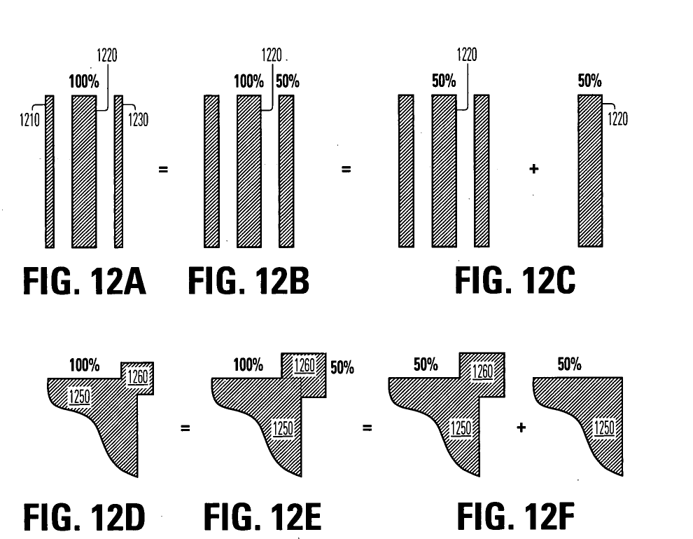

FIG. 12a-12f illustrates how assist lines or resolution enhancement assist features smaller than the capability of the mask process allows may be printed. FIG. 12a illustrates one line 1220 to be printed on a workpiece. For enhanced contrast and adjustment of the printed line width it is designed with scatter bars 1210 and 1230.

Imagine that a central line 1220 has a line width of 90 nm in wafer scale, and that two non-printing assist lines 1210, 1220 have a line width of 35 nm. Suppose that the mask process has a lower limit of 200 nm i.e. 50 nm in wafer scale with 4× reduction. It is thus possible to make a mask with the 90 nm line, but the 35 nm assist lines cannot be printed on the mask.

FIG. 12b illustrates how the invention can support the small assist lines: instead of using 100% exposure dose for all lines, only the central line 1220 is exposed with 100% exposure dose whereas the two assist lines 1210, 1230 are magnified to 70 nm width but exposed with only 50% exposure dose. This dividing of exposure doses is not easily done in a single writing pass, however as illustrated in FIG. 12c, the lines may be divided into two writing passes, both exposed with a 50% exposure dose. In a first writing pass both the assist lines 1210, 1230 together with the central line 1220 in exposed using 50% exposure dose. In a second writing pass only the central line 1220 is once more exposed with 50% exposure dose. The completed pattern on the workpiece will be similar to the one illustrated in FIG. 12a. The multiexposure-aware OPC software will simulate the two overlaid patterns in 12c and make any adjustments needed to make it print identically to 12a or rather to the intended image on the wafer.

FIG. 12d illustrates further example where the invention can support an aggressive lithography than previously used methods. A feature 1250 has a corner enhancement serif 1260. Said corner enhancement feature 1260 is smaller than the capability of the pattern generator. FIG. 12e illustrates an equivalent representation of FIG. 12d, where the corner enhancement feature 1260 is twice as large as in FIG. 12d but exposed to 50% dose. As mentioned in connection with FIG. 12, said corner enhancement feature is not easily exposed to 50% in the same writing pass as the feature 1250 is exposed to 100% dose. However, in the context of multi-exposures the pattern may be divided into two passes that are not identical. In a first writing pass said feature 1250 together with said corner enhancement feature 1260 are both exposed to 50% dose. In a second writing pass said feature 1250 is alone exposed to 50% dose.

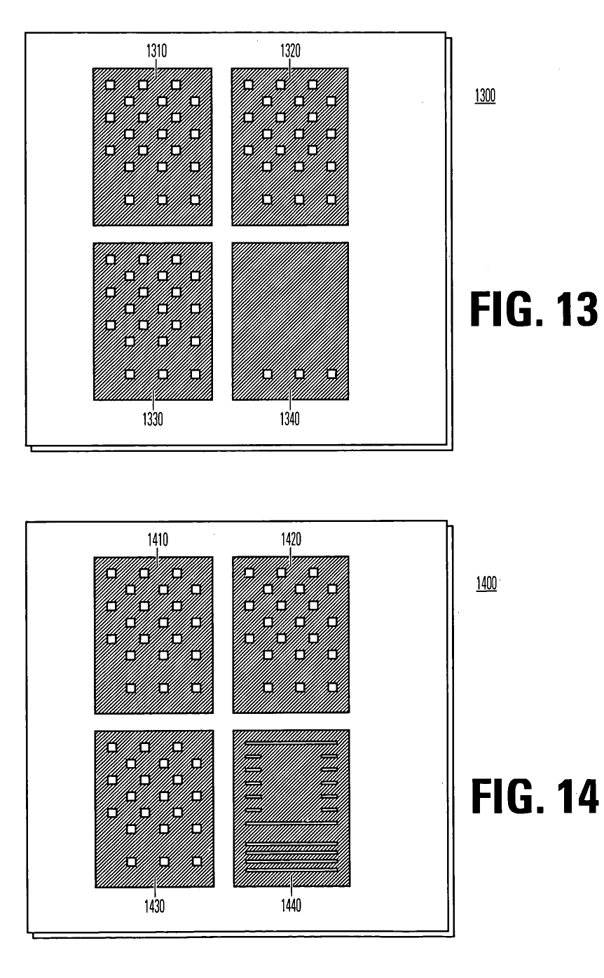

If the invention is used with three or more passes one pass can be set apart for CD adjustment while the remainder of the passes are used for speckle and error reduction through voting. FIG. 13 depicts a mask/reticle 1300 comprising four areas 1320, 1320, 1330, and 1340. Three of the areas 1310, 1320, and 1330 are identical. A fourth area 1340 has a different pattern compared to the other areas. On the wafer, printed with four passes, said areas 1310, 1320, 1330, and 1340 are all superimposed on each other, i.e., a four pass strategy is used where the reticle is displaced between the writing passes so that the different areas are superimposed on each other on said workpiece. The three identical superimposed passes create a voted image with reduced speckle and errors, and the fourth pass 1340 adjusts the CD of the semi-isolated contacts in the lower part of the figure. Without this adjustment they would print smaller and might create a yield issue.

FIG. 14 illustrates another example of a mask/reticle comprising four areas 1410, 1420, 1430, and 1440. Three of the areas are identical 1410, 1420, and 1430 and the fourth area 1440 differs from the other three. The pattern in the fourth area 1440 consists of non-printing figures that create a varying background that can be used to adjust the CD of features printed by the other three passes.

A further aspect of the invention is that the CD of the latent image in the resist can be measured by means of scatterometry before the last exposure pass and the dose of the last exposure pass can be modified to adjust CD to target. It is also possible to monitor the focus sensor during the passes and, if a focus error is detected, modify the focus in a later pass. The invention makes it possible to improve the printing quality more than by the statistical effect of voting alone is data from the stage and reticle servos, the dose monitors and the focus sensor is recorded and stored and used for feed-forward correction during a later pass. By feed-forward correction of previous errors a partial correction of said errors is possible and the printing quality is significantly improved.

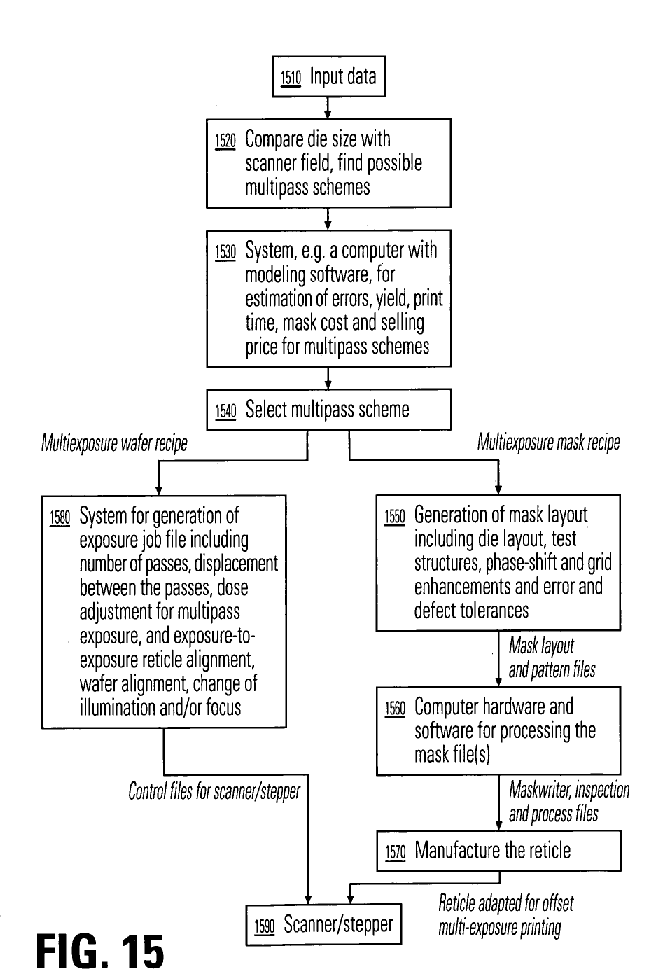

FIG. 15 illustrates a flow chart of an embodiment according to the present invention for generating the pattern data and the mask recipe, producing the reticle and creating the command files for printing multi-exposure voted patterns on a wafer.

Most steps in FIG. 15 need to be performed with awareness of the multi-exposure scheme, and using multiexposure-aware software modules interacting with the specifics of the exposure system. Therefore both the software modules, the file formats and the procedures are special for the invention, as is the reticle. The exposure system is adapted to the invention by suitable software modules and a dose control that allows independent setting of the exposure dose per pass and the number of pulses during each scan. Most suitably the exposure system has a laser power attenuator that can be controlled under software control to a range of at least 1:4, preferably to 1:10, and dose monitors and detectors are adapted to operation with a varying number of passes, i.e. with an exposure dose varying over a wide range. The invention is highly suitable for use in immersion lithography. Many issues with immersion, like dynamic focus effects and light scattering from micro-bubbles are averaged out by the multipass voting, and the generally augmented printing quality goes well with the critical applications for which immersion is used. Heating is reduced since the multipass voting exposure uses lower dose per pass. In particular hyper-NA (NA>1) systems benefit from the invention for two areas: polarisation and focus control. Polarised light will be a necessity with hyper-NA lithography and polarised light has more speckle, which is reduced by the invention. Focus control is improved by the voting, scanning every die in both directions, and by feed-forward focus correction based on focus sensor monitoring and/or recorded focus servo error signals.

At the top said flow chart starts with input data 1510. Said input data may for instance be the design of a memory or processor chip. A die size of said chip is in a next step compared to the size of a scanner field. Depending on the size of the chip one, two four or more chips may fit in the scanner field. In the next step 1530 printing time, errors, yield, mask cost, selling price are estimated for different number of dies in a single reticle in combination with different multipass writing strategies. Said estimation is preferably performed with support from a computer which is pre-programmed with parameters for the different set ups. From the result of the estimation is step 1530 a selection of multipass scheme is performed in step 1540.

After having selected the multipass scheme said flowchart is divided into two branches, one in which a multi-exposure mask recipe is generated and one in which a multi-exposure wafer recipe is generated. In step 1550 a mask layout is generated including die layout, test structures, and phase shifting, OPC and grid enhancements. This is supported by multiexposure-aware OPC software. Defect and error tolerances has been taken into account when generating said mask layout. In a next step 1560 said mask data file and maskwriter command file is provided to a mask writer, for instance Micronic Laser Systems' Omega 6000 series machines or Sigma 7000 series machines. In step 1570 said mask/reticle is manufactured. The setup of the inspection and repair step during manufacturing is done with knowledge of the voting exposure.

Having chosen the multi-exposure mask recipe said recipe is converted to a stepper/scanner recipe. In step 1580 a particular exposure job file is generated comprising the number of writing passes, displacement between the passes, dose adjustment for multipass exposure, and exposure-to-exposure reticle alignment, wafer alignment, change of illumination and/or focus and scan direction. This multi-exposure wafer recipe together with the manufacture reticle/mask is then provided to the scanner/stepper for producing said chip 1590.

Improvements of the stationary speckle. The stationary micro non-uniformities are a result of coherent beamlets being split and recombined in the illuminator. Constant path length between the split parts may create a stationary pattern that repeats pulse after pulse. In a scanner the laser typically has a pulse repletion rate of 4 kHz, and 20-100 pulses are used for the exposure, even more than 100 pulses may be used according to this invention. In a further aspect of the current invention the repetition pulse after pulse of the stationary speckle pattern is reduced by a time-varying phase scrambler in the illuminator, e.g. at lest one phase plate that is translated or rotated between pulses and/or between the passes. The laser may in one embodiment have a pulse FWHM duration shorter than 200 ns. In another embodiment according to the present invention said laser may have a FWHM duration shorter than 100 ns. In yet another embodiment according to the present invention said laser may have a FWHM duration shorter than 50 ns. In another embodiment according to the present invention an optical delay line is stretching the pulse to a FWHM duration longer than 50 ns. In still another embodiment according to the present invention an optical delay line is stretching the pulse to a FWHM duration longer than 100 ns.

In another embodiment according to the present invention said source has a FMHM bandwidth of less than 10 pm. In still another embodiment according to the present invention said source has an FMHM bandwidth of less than 1 pm. In still another embodiment according to the present invention said source has an FMHM bandwidth of less than 0.3 pm. In a further embodiment the laser has a FWHM bandwidth larger than 0.3 nm and the projection lens has color correction by a diffractive element.

In one embodiment according to the present invention the address grids are displaced between the dies by a fraction of an address unit, e.g., 1-99% of the address unit. In another embodiment according to the present invention at least one exposure pass is printed with a different focus relative to at least one other exposure pass.

In yet another embodiment according to the present invention N*Tₚ/t_{c}*(2−P)<10 000, where N is the number of pulses per exposure pass, Tₚ the pulse duration, t_{c} the coherence time (=the longitudinal coherence length over the velocity of light).

In yet another embodiment according to the present invention N*Tₚ/t_{c}*(2−P)<2500, where N is the number of pulses per exposure pass, Tₚ the pulse duration, t_{c} the coherence time (=the longitudinal coherence length over the velocity of light).

In still another embodiment according to the present invention the illumination of the workpiece has a degree of polarization P larger than 0.5.

To reduce the impact of the stationary speckle, which gives a stripe-like exposure variation in the scanning direction, it is further beneficial to displace the dies on the reticle in a direction across the scan and by an amount that is large compared to the lateral coherence length in the reticle plane. Since the lateral coherence length is typically less than a micron, such a displacement can be small enough not to cause any problems at the dicing operation. However, the displacement between the passes must take this shift into account in order to expose all passes perfectly on top of each other.

The reticle needs to be adapted to this invention so that it can be placed in alternative positions. One adaptation is that the saw lines (scribe lines) between the dies and between the scanner fields must be identical and that test structures in the saw lines must be duplicated so that that they are printed on top of each other in all passes. This means that they have to be placed both between and outside of the dies on the reticles, see FIG. 8.

Another aspect of the invention is that not only process errors in the reticle are averaged, but also systematic errors arising from the data input and data processing. With the invention it is possible to improve the address resolution above what the mask writer is capable of by printing the each die with the mask writer grid, and using the multi-exposure to create a finer address, as illustrated in FIG. 9a-9d.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

The invention is described with references to a stepper/scanner for printing on wafers. Other lithographic printers may use aspects of the invention with benefit. This is particularly true for SLM-based pattern generators for masks and wafers, as well as for other pattern generators. When applied to SLM pattern generators the invention has the SLM taking the place of the reticle. Aspects applicable to pattern generators are among others the modification of patterns between the exposure passes for resolution of phase conflicts and improvements of grid and OPC resolution, scrambling of the coherence in the illuminator, procedures and computer support for adjusting the number of exposure passes based on a trade-off between predicted quality and through-put, and multiple passes with symmetrical left-right (or up-down) stage movement at every point in the exposed pattern, use of scatterometry for feed-forward adjustment of CD, and feed-forward correction of focus errors.

### References

1. Title: Lithographic alternatives to PSM repair Author(s): Rieger, M. L.; Buck, P. D.; Shaw, A. Author Affiliation: Etec Syst. Inc., Beaverton, Oreg., USA Journal: Proceedings of the SPIE—The International Society for Optical Engineering vol.1674, pt.2 p.609-17
2. Title: Advances in 1:1 optical lithography Author(s): Stephanakis, A. C.; Rubin, D. I. Author Affiliation: Ultratech Stepper, Santa Clara, Calif., USA Journal: Proceedings of the SPIE—The International Society for Optical Engineering vol.772 p.74-85
3. Title: A novel technique for detecting lithographic defects Author(s): McCarthy, A. M.; Lukaszek, W.; Fu, C. C.; Dameron, D. H.; Meindl, J. D. Author Affiliation: Center for Integrated Syst., Stanford Univ., Calif., USA Journal: IEEE Transactions on Semiconductor Manufacturing vol.1, no.1 p.10-15

1. A method for patterning a workpiece using a lithographic printer and a mask or reticle having at least first and second areas, the method including:
patterning at least an area of a radiation sensitive layer on the workpiece, which is sensitive to a radiation source, by illuminating said first area on the mask or reticle with at least one pulse of radiation; and
patterning the same area of the radiation sensitive layer by illuminating said second area on the mask or reticle with at least one pulse of the radiation.

2. The method of claim 1, further including:
coating said workpiece with the radiation sensitive layer; and
placing said workpiece on a workpiece stage in the lithographic printer, said printer including the reticle or mask disposed between said radiation source and said workpiece, wherein the first and second areas have essentially equal patterns.

3. The method according to claim 1, wherein said lithographic printer is a device selected from the group consisting of a scan-and-repeat mask aligner, a step and repeat mask aligner and a proximity mask aligner.

4. The method according to claim 1, wherein said first and second areas on the mask or reticle are mask images of a chip (“die”).

5. The method according to claim 1, wherein said radiation source is a pulsed laser with a pulsed laser.

6. The method according to claim 1, wherein said radiation source is a pulsed laser with a pulse FWHM duration shorter than 200 ns.

7. The method according to claim 1, wherein said radiation source is a pulsed laser with a pulse FWHM duration shorter than 100 ns.

8. The method according to claim 1, wherein said radiation source is a pulsed laser with a pulse FWHM duration shorter than 50 ns.

9. The method according to claim 1, wherein said radiation source has an optical delay line stretching a pulse to FWHM duration larger than 50 ns.

10. The method according to claim 1, wherein said radiation source has an optical delay line stretching a pulse to FWHM duration larger than 100 ns.

11. The method according to claim 1, wherein said radiation source is a pulsed laser with a wavelength of 248 nm.

12. The method according to claim 1, wherein said radiation source is a pulsed laser with a wavelength of 193 nm.

13. The method according to claim 1, wherein said radiation source produces EUV radiation with an exposing wavelength in the range of 5-20 nm.

14. The method according to claim 1, wherein said radiation has an FWHM bandwidth of less than 10 pm.

15. The method according to claim 1, wherein said radiation has an FWHM bandwidth of less than 1 pm.

16. The method according to claim 1, wherein said radiation has an FWHM bandwidth of less than 0.3 pm.

17. The method according to claim 1, wherein the radiation illuminates of the workpiece with a degree of polarization P larger than 0.5.

18. The method according to claim 1, where N*Tₚ/t_{c}*(2−P)<10,000 and where N is a number of pulses per exposure pass, Tₚ a pulse duration, t_{c} a coherence time, and P is a factor from 0 to 1, with 0 denoting non-polarized and 1 fully polarized light.

19. The method according to claim 1, where N*Tₚ/t_{c}*(2−P)<2500 and where N is a number of pulses per exposure pass, Tₚ a pulse duration, t_{c} a coherence time, and P is a factor from 0 to 1, with 0 denoting non-polarized and 1 fully polarized light.

20. The method according to claim 1, wherein the mask has areas for exposing at least two dies with a known displacement vector between the areas and the stage is offset by the same displacement vector between two exposure passes.

21. The method according to claim 1, wherein the mask has areas for exposing an array of at least 2×2 dies with known x and y displacement vectors between the areas corresponding to the dies and the stage is offset by the x displacement vector between at least two exposure passes and by the y displacement vector between at least two exposure passes.

22. The method according to claim 1, wherein the lines between dies within a scanner field and between scanner fields are essentially equal in width.

23. The method according to claim 1, wherein test structures are placed both between dies within a scanner field and between scanner fields.

24. The method according to claim 1, wherein test structures are placed both between dies within a scanner field and between scanner fields, at least part of said test structures between dies and between fields being essentially identical.

25. The method according to claim 1, wherein first and second address grids, to which patterning through the first and a second areas on the mask or reticle are aligned, are displaced by a fraction of an address unit.

26. The method according to claim 1, wherein at least two patterning steps are printed with different focus.

27. The method according to claim 2, wherein a phase plate in the radiation source is moved between the exposure passes.

28. The method according to claim 2, wherein a phase plate in the radiation source is moved between the exposure passes and between laser pulses.

29. The method according to claim 1, wherein said first and said second areas of said mask or reticle include clear and opaque areas.

30. The method according to claim 1, wherein said first and said second areas of said mask or reticle include clear and attenuating phase shifted areas.

31. The method according to claim 1, wherein said first and said second areas of said mask or reticle include clear and phase shifted areas with essentially equal transmission of radiation.

32. The method according to claim 1, wherein said first and said second areas of said mask or reticle include opaque areas, and clear and phase shifted areas with essentially equal transmission of radiation.

33. The method according to claim 1, wherein said first and said second areas of said mask or reticle include clear and phase shifted areas and at least two clear and shifted areas are reversed between patterning with the first and second areas.

34. The method according to claim 1, wherein said first and said second areas of said mask or reticle include clear and phase shifted areas and at least one boundary between a clear and a shifted area is placed differently in the first and second areas.

35. The method according to claim 1, wherein said first and said second areas of said mask or reticle is provided with sub-resolution assist features (SRAFs) and at least one SRAF is different patterning with the first and second areas.

36. The method according to claim 1, wherein said first and said second areas of said mask or reticle is provided with OPC corrections (“jogs”) and at least one jog is patterning with the first and second areas.

37. The method according to claim 1, wherein said first and said second areas of said mask or reticle include serifs and at least one serif is different between the first and second areas.

38. The method according to claim 1, wherein at least one feature is defined by a phase edge in one exposure pass and a trim mask in another pass.

39. The method according to claim 1, wherein at least one feature is absent from the first or second areas.

40. The method according to claim 1, wherein at least one area on the mask produces a non-printing background.

41. The method according to claim 1, wherein at least one area on the mask has a DOE.

42. A device manufactured according to claim 1.

43. The method according to claim 1, wherein said first and said second areas of said mask or reticle is provided with clear and phase shifted areas.

44. The method according to claim 2, wherein said phase shifted and clear areas in said first area of said mask or reticle are rearranged in said second area of said mask or reticle.

45. The method according to claim 1, further including:
stretching at least one of said pulses which is exposing said same area of the workpiece.

46. The method according to claim 1, wherein two pulses which are exposing said same area of the workpiece differing in doses.

47. A method of reducing static speckle produced by a projection system used to expose a radiation sensitive layer on a workpiece, the method including repositioning a phase plate along a projection access of the projection system when patterning a die on the workpiece.

48. The method of claim 47, wherein the phase plate is repositioned between patterning of the die on the workpiece by illuminating first and second areas of a mask or reticle with pulsed radiation.

49. The method of claim 47, wherein the phase plate is repositioned between pulses used to illuminate one or more areas of a mask or reticle.

50. A reticle or mask for use in multipass exposure, including
a transmissive substrate,
a patterned opaque layer including a plurality of areas on one side of said transmissive substrate, the plurality of areas being intended to mask radiation projected on a particular area of a workpiece in different exposure passes, wherein at least one area on said reticle or mask is different to other areas.

51. The reticle or mask according to claim 50, wherein at least one phase shifted area is arranged differently in said at least one area of the reticle or mask compared to other areas.

52. The reticle or mask according to claim 50, wherein said at least one area of the reticle or mask has a DOE.

53. The reticle or mask according to claim 50, wherein said at least one area of the reticle or mask has a non-printing background.

54. The reticle or mask according to claim 50, wherein at least one feature is absent in said at least one area of the reticle or mask.

55. The reticle or mask according to claim 50, wherein said at least one die on the mask or reticle is provided with at least one sub-resolution assist feature (SRAF).

56. The reticle or mask according to claim 50, wherein said at least one area of the reticle or mask includes at least one more sub-resolution assist feature (SRAF) compared to other areas.

57. The reticle or mask according to claim 50, wherein said at least one area of the reticle or mask includes at least one boundary between a clear and a shifted areas that is differently arranged compared to other areas on the same reticle or mask.

58. The reticle or mask according to claim 50, wherein scribe lines between areas within a scanner field and between scanner fields are essentially identical.

59. The reticle or mask according to claim 50, wherein test structures are placed both between areas within a scanner field and between scanner fields.

60. The reticle or mask according to claim 50, wherein test structures are placed both between areas within a scanner field and between scanner fields, said test structures between areas and between fields being essentially identical.

61. The reticle or mask according to claim 50, wherein said at least one areas on the mask or reticle is provided with OPC corrections (“jogs”) and at least one jog is different compared to at least one other area on said reticle or mask.

62. The reticle or mask according to claim 50, wherein said at least one area on the mask or reticle is provided with serifs and at least one serif is different compared to at least other areas on said reticle or mask.

63. The reticle or mask according to claim 50, wherein at least one feature is defined by a phase edge in one die and a trim mask in another area on the same reticle or mask.
